(19) United States
(12) Patent Application Publication
(10) Pub. No.: US 2026/0339195 A1
(43) Pub. Date: Oct. 29, 2026

(54) PELLICLE AND METHOD FOR EXTREME ULTRAVIOLET LITHOGRAPHY

(71) Applicant: Taiwan Semiconductor Manufacturing Company, Ltd., Hsinchu (TW)

(72) Inventors: Ching-Yu CHANG, Hsinchu (TW); Jr-Yu CHEN, Hsinchu (TW); Jr-Hung LI, Hsinchu (TW); Chung-Chi KO, Hsinchu (TW); Wei-Hao LEE, Hsinchu (TW); Ting-Pi SUN, Hsinchu (TW)

(73) Assignee: Taiwan Semiconductor Manufacturing Company, Ltd., Hsinchu (TW)

(21) Appl. No.: 19/189,552

(22) Filed: Apr. 25, 2025

(51) Int. Cl. G03F 1/62

(52) U.S. Cl. CPC G03F 1/62

(57) ABSTRACT

A pellicle for protecting a photomask from contaminant particles during photolithography is provided. The pellicle includes a pellicle membrane having a network of carbon nanotube structures with at least one dielectric passivation film and at least one metal layer. The pellicle membrane is attached to a pellicle frame that is mounted to a photomask to be used during photolithography operations.

### BACKGROUND

In the semiconductor integrated circuit (IC) industry, technological advances in materials and design have produced ICs where each generation has smaller and more complex circuits than the previous generation. The functional density (i.e., the number of interconnected devices per chip area) has generally increased while geometry size (i.e., the smallest component (or line) that can be created using a fabrication process) has decreased. This scaling-down process generally provides benefits by increasing production efficiency and lowering associated costs but also has increased the complexity of IC processing and manufacturing.

During a photolithography process, a patterned resist layer is formed for various patterning processes, such as etching or ion implantation. The minimum feature size that may be patterned by way of such a photolithography process is limited by the wavelength of the projected radiation source. Existing photolithography equipment uses deep ultraviolet (DUV) light including a krypton fluoride laser (KrF laser) of 248 nanometers (nm) and an argon fluoride laser (ArF laser) of 193 nm, as well as extreme ultraviolet (EUV) light of a wavelength of 13.5 nm.

In the photolithography process, a photomask is used. The photomask includes a substrate and a patterned layer that defines an IC to be transferred to a semiconductor substrate during the photolithography process. The photomask is typically included with a pellicle. The pellicle includes a transparent thin membrane and a pellicle frame, where the membrane is mounted over the pellicle frame. The pellicle protects the photomask from fallen particles and keeps the particles out of focus so that they do not produce a patterned image, which may cause defects when the photomask is being used. Existing pellicles are exposed to harsh photolithography conditions and the optical performance of the pellicle may be subject to degradation due to exposure to temperature and light. There remains room for improved pellicle materials with EUV exposure stability and optimized mechanical and optical properties.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of a photolithography system constructed in accordance with some embodiments of the present disclosure.

FIG. 2A is a cross-sectional view of a photomask-pellicle assembly, according to some embodiments of the present disclosure.

FIG. 2B is an exploded view of a pellicle, according to some embodiments of the present disclosure.

FIG. 2C is a schematic perspective view of a nanotube, according to some embodiments of the present disclosure.

FIG. 3A is a cross-sectional view of a carbon nanotube structure, according to some embodiments of the present disclosure.

FIG. 3B is a cross-sectional view of a carbon nanotube structure, according to some embodiments of the present disclosure.

FIG. 4 is a cross-sectional view of a carbon nanotube structure, according to some embodiments of the present disclosure.

FIG. 5A is a cross-sectional view of a carbon nanotube structure, according to some embodiments of the present disclosure.

FIG. 5B is a cross-sectional view of a carbon nanotube structure, according to some embodiments of the present disclosure.

FIG. 6A is a sectional view of a carbon nanotube structure, according to some embodiments of the present disclosure.

FIG. 6B is a sectional view of a carbon nanotube structure, according to some embodiments of the present disclosure.

FIG. 6C is a schematic illustration showing film coatings of a carbon nanotube structure, according to some embodiments of the present disclosure.

FIG. 7 is a flow diagram illustrating a method of forming a photomask-pellicle assembly, according to at least one embodiment of the present disclosure.

FIG. 8 illustrates a flowchart of a method of manufacturing a semiconductor device, according to at least one embodiment of the present disclosure.

### DETAILED DESCRIPTION

It is to be understood that the following disclosure provides many different embodiments, or examples, for implementing different features of the present application. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B, and one from C, unless otherwise explained.

In one embodiment of the present disclosure, a durable, high-transmission pellicle used with EUV lithography equipment is provided. In certain embodiments, an EUV lithography scanner uses EUV radiation to project a pattern formed in a photomask onto a silicon wafer and the pattern may be etched into the wafer. In some examples, the pellicle is used to protect the photomask from contamination falling on the photomask and resulting in critical dimension error. The EUV environment generates a plasma environment containing hydrogen ions and radicals that can have deleterious effects on the pellicle. Embodiments of the present disclosure provide a pellicle that has increased pellicle transmittance, as well as a resistance to reactive chemicals including resistance to degradation by hydrogen ions and radicals.

In one example, the pellicle includes a membrane comprising carbon nanotubes (CNT) that increases optical transmittance during EUV exposure. In some embodiments, the CNT structure includes at least one dielectric passivation film and a metal layer disposed on the surfaces of CNTs to protect the CNT pellicle membrane. In other embodiments, the CNT structure includes at least one dielectric passivation film and at least one metal seed layer disposed on the surfaces of CNTs to protect the CNT pellicle membrane.

In some examples, the CNT pellicle membrane of the present disclosure reduces the amount of EUV dosage needed due to its increased transmittance and reduces surface defects on the photomask. In some examples, the CNT pellicle membrane includes a hydrogen-resistant film stack that prolongs the exposure lifetime of the pellicle. The CNT pellicle membrane of the present disclosure is mechanically robust and is EUV-durable while allowing for improved transmission of radiation.

Additional features can be added to the pellicle disclosed herein. Some of the features described below can also be replaced or eliminated for different examples. Although some examples disclosed below discuss operations that are performed in a particular order, these operations may be performed in other orders as well without departing from the scope of the present disclosure. Throughout the various views and illustrative embodiments, like reference numbers are used to designate like elements.

Moreover, in other examples, the pellicle and methods disclosed herein may be deployed in a plurality of applications, including the fabrication of transistors. For instance, in certain examples of the present disclosure the patterning features including lines, trenches, or vias are provided with reduced spacing between features.

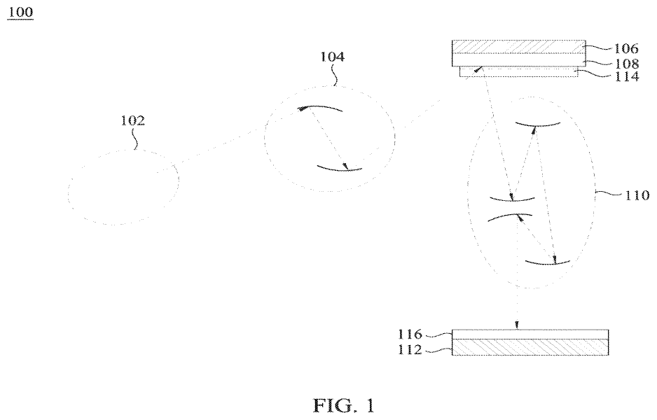

FIG. 1 is a simplified schematic diagram of a photolithography system 100 according to examples of the present disclosure. The photolithography system 100 may also be referred to herein as a scanner that is operable to perform photolithography exposing processes with respective radiation sources and exposure modes.

In one example, the photolithography system 100 includes an exposure light source 102, an illuminator 104, a mask stage 106, a photomask 108, a projection optics module 110, and a substrate stage 112. In some examples, the photolithography system 100 includes additional components that are not illustrated in FIG. 1. In further examples, one or more of the light source 102, the illuminator 104, the mask stage 106, the photomask 108, the projection optics module 110, and the substrate stage 112 are omitted from the photolithography system 100 or are integrated into combined components. In some embodiments, the photomask 108 is loaded into the photolithography system 100 and the semiconductor wafer 116 is loaded onto the substrate stage 112 of the photolithography system 100.

In certain embodiments, the light source 102 is configured to emit radiation having wavelengths in the range of approximately 1 nanometer to 250 nm. In one particular example, the light source 102 generates EUV light with a wavelength centered at approximately 13.5 nm; accordingly, in some examples, the light source 102 may also be referred to as an EUV light source. However, it will be appreciated that the light source 102 is not limited to emitting EUV light. For instance, the light source 102 is utilized to perform any high-intensity photon emission from an excited target material.

In some examples (e.g., where the photolithography system 100 is a UV lithography system), the illuminator 104 includes various refractive optical components, such as a single lens or a lens system comprising multiple lenses (zone plates). In another example (e.g., where the photolithography system 100 is an EUV lithography system), the illuminator 104 comprises various reflective optical components, such as a single mirror or a mirror system comprising multiple mirrors. The illuminator 104 may direct light from the exposure light source 102 onto the mask stage 106, and more particularly onto the photomask 108 that is secured onto the mask stage 106. In an example where the light source 102 generates light in the EUV wavelength range, the illuminator 104 comprises reflective optics.

In some embodiments, the mask stage 106 is configured to secure the photomask 108. In some examples, the mask stage 106 includes an electrostatic chuck (e-chuck) to secure the photomask 108. Because gas molecules absorb EUV light, the photolithography system 100 for EUV lithography patterning is maintained in a vacuum environment to minimize EUV intensity loss. Herein, the terms photomask, mask, and reticle may be used interchangeably. In one example, the photomask 108 is a reflective mask.

In some embodiments of the present disclosure, a pellicle 114 is positioned over the photomask 108, e.g., between the photomask 108 and the substrate stage 112. The pellicle 114 may protect the photomask 108 from particles and may keep the particles out of focus so that the particles do not produce an image (which may cause defects on a semiconductor wafer 116 during the photolithography process).

In some embodiments, the projection optics module 110 is configured for imaging the pattern of the photomask 108 onto a semiconductor wafer 116 secured on the substrate stage 112. In one example, the projection optics module 110 comprises refractive optics (such as for a UV lithography system). In another example, the projection optics module 110 comprises reflective optics (such as for an EUV lithography system). The light directed from the photomask 108, carrying the image of the pattern defined on the photomask 108, is collected by the projection optics module 110. The illuminator 104 and the projection optics module 110 may be collectively referred to as an optical module of the photolithography system 100.

In some examples, the semiconductor wafer 116 may be a bulk semiconductor wafer. In some embodiments, the semiconductor wafer 116 includes a silicon wafer. In other examples, the semiconductor wafer 116 includes another elementary semiconductor material, such as germanium. In some examples, the semiconductor wafer 116 includes a compound semiconductor. In other examples, the compound semiconductor includes gallium arsenide, silicon carbide, indium arsenide, indium phosphide, another suitable material, or a combination thereof. In yet other examples, the semiconductor wafer 116 includes a silicon-on-insulator (SOI) substrate. In certain embodiments, the SOI substrate is fabricated using a separation by implantation of oxygen (SIMOX) process, a wafer bonding process, another applicable process, or a combination thereof. In some examples, the semiconductor wafer 116 comprises an undoped substrate. However, in other examples, the semiconductor wafer 116 comprises a doped substrate, such as a p-type substrate or an n-type substrate.

In some examples, the semiconductor wafer 116 includes various doped regions (not shown) depending on the design requirements of the semiconductor device structure. The doped regions may include, for example, p-type wells and/or n-type wells. In some examples, the doped regions are doped with p-type dopants such as boron or boron fluoride. In other examples, the doped regions are doped with n-type dopants such as phosphorus or arsenic. In some examples, some of the doped regions are p-doped and other doped regions are n-doped.

In some embodiments, an interconnection structure is formed over the semiconductor wafer 116. The interconnection structure includes multiple interlayer dielectric layers, including dielectric layers. In some embodiments, the interconnection structure includes multiple conductive features formed in the interlayer dielectric layers. In certain embodiments, the conductive features include conductive lines, conductive vias, and/or conductive contacts.

In some examples, various device elements are formed on the semiconductor wafer 116. Examples of the various device elements include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel, and/or n-channel field effect transistors (PFETs and/or NFETs), diodes, or other suitable elements. In some embodiments, various processes are used to form the various device elements, including deposition, etching, implantation, photolithography, annealing, and/or other applicable processes.

In some embodiments, the device elements are interconnected through the interconnection structure over the semiconductor wafer 116 to form IC devices. In some embodiments, the IC devices include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some examples, the semiconductor wafer 116 is coated with a resist layer that is sensitive to actinic radiation, such as DUV or EUV light. In other embodiments, the various components including those described above are integrated and are operable to perform lithography-exposing processes.

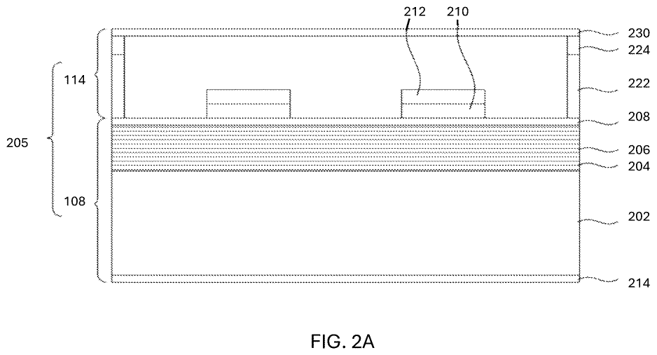

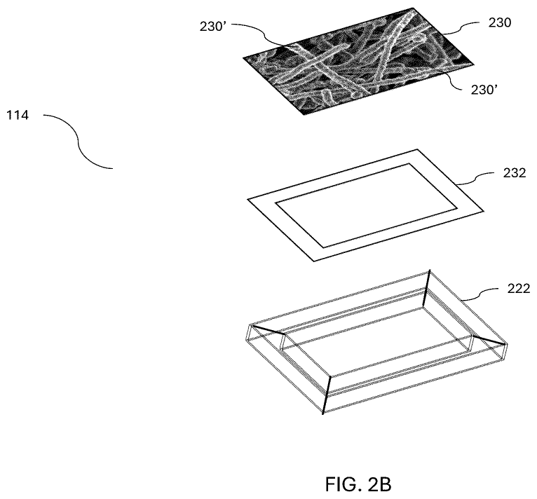

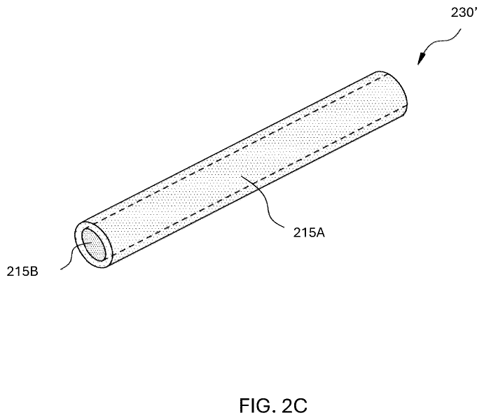

FIG. 2A illustrates a cross-sectional view of a photomask-pellicle assembly 205 used in photolithography, according to some embodiments. The photomask-pellicle assembly 205 includes a photomask 108 and a pellicle 114. The illustrative photomask 108 is a reflective mask of a type used in EUV lithography and includes a substrate 202, alternating reflective layers 204 and spacing layers 206, and a capping layer 208, an EUV absorbing layer 210 that is patterned to define a pattern region or surface of the photomask, an anti-reflective coating (ARC) 212, and a conductive backside layer 214. The illustrative photomask 108 is a non-limiting example. The pellicle 114 as disclosed herein is used with any suitable reflective or transmission reticle in some embodiments. As another example (not shown), the photomask 108 is a transmission reticle, in which case the substrate is transmissive for light at the wavelength at which the photolithography is performed. In general, the reflective or transmissive reticle includes a substrate (e.g., substrate 202) and a mask pattern (e.g., absorbing layer 210) disposed on the substrate 202. As illustrated in the embodiment of FIG. 2A, the pellicle 114 includes a mounting frame 222, an adhesive layer 224, and a CNT pellicle membrane 230. In some embodiments, the photomask-pellicle assembly 205 is used with EUV light wavelengths, for example from about 10 nm to about 124 nm, including about 13.5 nm.

In some embodiments, the substrate 202 is made from a low thermal expansion material (LTEM), such as quartz or titania silicate glasses. In some examples, the substrate 202 includes a transparent substrate, such as fused silica that is substantially free of defects, borosilicate glass, soda-lime glass, calcium fluoride, low thermal expansion material, ultra-low thermal expansion material, or other applicable materials. The substate 202 helps reduce or prevent warping of the reticle due to the absorption of energy and consequent heating. The reflective layers 204 and the spacing layers 206 cooperate to form a Bragg reflector for reflecting EUV light. In some embodiments, the reflective layers 204 include molybdenum (Mo) and the spacing layers 206 include silicon (Si). The capping layer 208 is used to protect the reflector formed from the reflective layers 204 and the spacing layers 206, for example from oxidation and etching. In some embodiments, the capping layer 208 includes ruthenium (Ru). The EUV absorbing layer 210 absorbs EUV wavelengths and is patterned with the desired pattern. In some embodiments, the EUV absorbing layer 210 includes tantalum boron nitride. The anti-reflective coating (ARC) 212 further reduces reflection from the EUV absorbing layer. In some embodiments, the anti-reflective coating 212 includes oxidized tantalum boron nitride. The conductive backside layer 214 permits the mounting of the illustrative reticle on an electrostatic chuck and temperature regulation of the mounted substrate 202. In some embodiments, the conductive backside layer 214 includes chrome nitride.

The pellicle 114 includes a mounting frame 222 that supports the CNT pellicle membrane 230 at a height sufficient so that the CNT pellicle membrane 230 outside the focal plane of the photolithography, e.g., several millimeters (mm) over the photomask 108 in some non-limiting illustrative embodiments. In some embodiments, the mounting frame 222 itself is made from suitable materials, such as anodized aluminum, stainless steel, plastic, silicon (Si), titanium, silicon dioxide, aluminum oxide (Al₂O₃), or titanium dioxide (TiO₂). In some examples, suitable processes for forming the mounting frame 222 include machining processes, sintering processes, photochemical etching processes, other applicable processes, or a combination thereof.

In other embodiments, vent holes (not shown) are provided in the mounting frame 222 for equalizing pressure on both sides of the CNT pellicle membrane 230. In some examples, the vent structure includes one or more apertures formed in a side portion of the mounting frame 222. In some embodiments, the apertures take any shape, including circular apertures, rectangular apertures, slit-shaped apertures, other shapes, or any combination thereof. In some embodiments, the apertures allow for a flow of the ambient atmosphere in the photolithography system through a portion of the photomask-pellicle assembly 205. In some examples, the apertures include filters to minimize the passage of outside particles through the vent holes. In some examples, the vent holes are formed using a photochemical etching process, another applicable process, or a combination thereof.

In some embodiments, the adhesive layer 224 secures the CNT pellicle membrane 230 to the mounting frame 222. Suitable adhesives may include silicone, epoxy, thermoplastic elastomer rubber, acrylic polymer, acrylic copolymer, or combinations thereof. In some embodiments, the adhesive layer 224 has a crystalline and/or amorphous structure. In some embodiments, the adhesive layer 224 has a glass transition temperature (Tg) that is above a maximum operating temperature of the photolithography system, to prevent the adhesive from exceeding the Tg during the operation of the system.

In some examples, the adhesive layer 224 includes heat-dissipating fillers. The heat-dissipating fillers may include, for example, aluminum nitride, boron nitride, aluminum oxide, magnesium oxide, silicon oxide, graphite, metal powder, ceramic powder, another suitable material, or a combination thereof. In some examples, the EUV lithography process uses an EUV light beam that penetrates the CNT pellicle membrane 230, causing the temperature of the CNT pellicle membrane 230 to increase. The heat-dissipating fillers may help to dissipate the heat of the CNT pellicle membrane 230 through the adhesive layer 224, to the mounting frame 222, to the photomask 108, and to the EUV lithography scanner. Thus, in some embodiments, the maximum temperature of the CNT pellicle membrane 230 is reduced during EUV lithography processing using pellicles according to embodiments of the disclosure, thereby reducing the likelihood of the CNT pellicle membrane 230 rupturing.

In some examples, a surface treatment is performed on the mounting frame 222 to enhance the adhesion of the mounting frame 222 to the adhesive layer 224. In some examples, the surface treatment includes an oxygen plasma treatment, another applicable treatment, or a combination thereof. However, in other examples, no surface treatment is performed on the mounting frame 222.

FIG. 2B is an exploded view of a pellicle 114 in accordance with some embodiments of the present disclosure. In the embodiment of FIG. 2B, the CNT pellicle membrane 230 is enclosed or attached within a border frame 232. In some embodiments, the border frame 232 is attached to a peripheral edge of the CNT pellicle membrane 230. In certain embodiments, the border frame 232 is fixed to the mounting frame 222 by way of an adhesive layer 224 (FIG. 2A). The pellicle 114 is then fixedly mounted on the photomask 108. In certain embodiments, the pellicle 114 is fixedly secured to the photomask 108 with an adhesive or the like.

In some embodiments of the present disclosure, the use of CNT structures in the CNT pellicle membrane 230 provides a membrane that exhibits mechanical and optical properties that deliver effective or advantageous performance during the use of the pellicle membrane in EUV lithography. Other useful physical properties include resistance to high temperature and resistance to reactive chemicals (especially resistance to degradation by hydrogen radicals).

In certain embodiments, the CNT pellicle membrane 230 is a single or multi-layer membrane formed from a network of CNTs 230′. In the embodiment of FIG. 2C, a schematic perspective view of one CNT 230′ is shown. In some embodiments, each CNT 230′ has a core-shell structure 215A including a nanotube core 215B extending to both ends of the core-shell structure 215A. In some embodiments, the ends are open. In other embodiments, the ends are closed. In some embodiments, the carbon nanotube includes both a single wall CNT and multiwall carbon nanotube. In some embodiments, the single wall CNT 230′ has a diameter of about 0.5 nm to about 2 nm. In some embodiments, the multi-wall CNT 230′ has a diameter of about 5 nm to about 30 nm.

In certain embodiments, a pellicle membrane 230 as described, by containing CNTs 230′, is both very thin and lightweight. In some embodiments, the CNT pellicle membrane 230 is a thin membrane containing a network of CNTs 230′. In some embodiments, the CNT pellicle membrane 230 includes a network of CNTs 230′ dispersed within the CNT pellicle membrane 230, and connected or interconnected to form a thin but cohesive membrane. In certain embodiments, the CNTs 230′ include various molecular and structural arrangements. In certain embodiments, the CNTs 230′ include a morphology arranged in a periodic nanocrystalline form, an amorphous form, or a polycrystalline form.

In certain embodiments, the network of CNTs 230′ making up the CNT pellicle membrane 230 has a structure density sufficient to maximize EUV radiation transmission while minimizing the passage of particles through the CNT pellicle membrane 230. For instance, although a looser structure density may allow for greater EUV radiation transmission, the looser structure density may also allow particles to fall through to the photomask 108. In certain embodiments, the CNT pellicle membrane 230 including the CNTs 230′ is formed by a roll-to-roll process, another suitable process, or any combination thereof.

In some embodiments, the CNT pellicle membrane 230 is a single layer. In other embodiments, the CNT pellicle membrane 230 is a multilayer. In some embodiments, the layers of the multi-layer structure can be made of the same materials, and in other embodiments, the layers of the multi-layer structure can be made of different materials selected for particular purposes and arranged in order as desired. In some embodiments, the CNT pellicle membrane 230 has a thickness between about 5 nm to about 15 nm. In other embodiments, the CNT pellicle membrane 230 has a thickness of about 10 nm to about 12 nm.

In certain embodiments, an initial CNT pellicle membrane 230 is formed from bundles or a network of the CNTs 230′. In some embodiments, the bundles of the CNTs 230′ are arranged next to each other. Without being bound by any one particular theory, it is believed that the bundles of the CNTs 230′ are held together by van der Waals forces of sufficient strength to form the initial carbon nanotube membrane. In certain embodiments, the initial carbon nanotube membrane is annealed at temperatures of about 1000 °C to about 2000 °C. In certain embodiments, the initial carbon nanotube membrane is treated to reduce its thickness and obtain the CNT pellicle membrane 230. In certain embodiments, the initial nanotube membrane undergoes compression or immersion in a solution to obtain the desired thickness.

In some embodiments, the bundle or network of CNTs 230′ is formed using several different fabrication processes. For example, fabrication processes such as chemical vapor deposition (CVD), floating catalyst CVD, plasma-enhanced CVD, electrophoretic deposition; dispersal in a solution and concentration by removal of the solvent, vacuum filtration, and the like. In some embodiments, the CNT structures are formed by directly spinning carbon nanotubes from a floating catalyst CVD system. The direct spinning process begins by providing a reactor vessel. In some examples, the reactor vessel is equipped with a heat source to ensure a specified temperature in the reactor vessel. In certain embodiments, the CNT structures are then grown in the vessel and form an aerogel that is then capable of being spun into a fiber.

In certain embodiments, the CNT pellicle membrane 230 has a Young's modulus between about 1.18 TPa and about 1.33 TPa; a maximum tensile strength between about 30 GPa to about 100 GPa; a thermal conductivity of about 3,000 W/m K to about 4,000 W/m K; and is stable up to a temperature of about 800 °C in air.

In some embodiments, the CNTs 230′ of the CNT pellicle membrane 230 are randomly oriented or are directionally oriented in a desired direction. In some embodiments, the CNTs 230′ of the CNT pellicle membrane 230 are all randomly oriented. In some embodiments, the CNTs 230′ of the CNT pellicle membrane 230 are all directionally oriented. In these embodiments, the directionally oriented CNTs 230′ are aligned at an angle (e.g., 0 to 180 degrees) relative to each other.

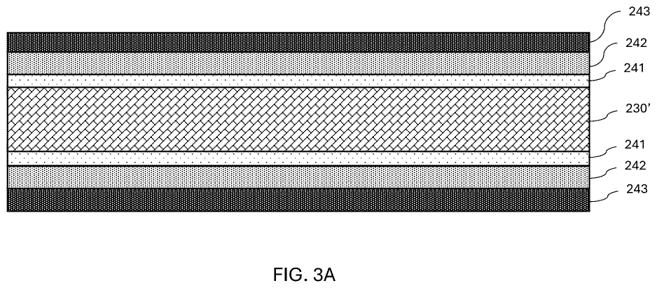

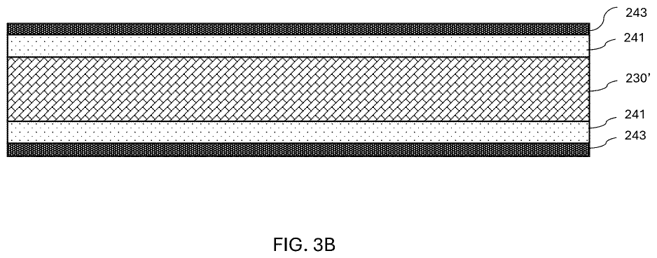

In the embodiment of FIG. 3A, a cross-sectional view of a CNT 230′ including a first dielectric passivation film 241 disposed on an outer surface of the CNT 230′ and a second dielectric passivation film 242 disposed on the first dielectric passivation film 241. In the embodiment of FIG. 3A, a metal layer 243 is disposed on the second dielectric passivation film 242.

In some embodiments, the first dielectric passivation film 241 and the second dielectric passivation film 242 include at least one of oxides, nitrides, or oxynitrides of silicon, titanium, or aluminum. In some examples, the materials for the first dielectric passivation film 241 and the second dielectric passivation film 242 are selected from SiO, SiN, SiOₓN_{y}, TiO₂, TiN, TiOₓN_{y}, TiSiO, TiSiN, Al₂O₃, AlON, AlN and/or the combination thereof. In some embodiments, the presence of the first and second dielectric passivation films 241, 242 improve the transmittance of the CNT pellicle membrane 230. In some embodiments, the first dielectric passivation film 241 includes a silicon oxide and the second dielectric passivation film 242 includes a silicon nitride. In other embodiments, the first dielectric passivation film 241 includes a silicon nitride and the second dielectric passivation film 242 includes a silicon oxide. In some embodiments, the first dielectric passivation film 241 and the second dielectric passivation film 242 are deposited by physical vapor deposition (PVD), chemical vapor deposition (CVD), plasma-enhanced CVD, atomic layer deposition (ALD), plasma-enhanced ALD, e-beam evaporation, electroless deposition, electrodeposition, or ion beam deposition (IBD).

In some embodiments, the metal layer 243 is a metal or metal oxide. In some embodiments, the metal layer 243 includes a metal selected from ruthenium (Ru) or titanium (Ti). In other embodiments, the metal layer 243 includes a metal oxide selected from a ruthenium oxide or a titanium oxide. In some embodiments, the presence of the metal layer provides improved protection of the CNT pellicle membrane 230 from hydrogen radicals and ions during EUV or DUV exposure. In some embodiments, the metal layer 243 is deposited by PVD, CVD, plasma-enhanced CVD, ALD, plasma-enhanced ALD, e-beam evaporation, electroless deposition, electrodeposition, or IBD.

In some examples, the first dielectric passivation film 241 has a thickness range of about 5 to about 20 Angstroms (Å). In some examples, the second dielectric passivation film 242 has a thickness range of about 5 to about 20 Å. In some embodiments, the metal layer 243 has a thickness range of about 5 to about 10 Å. In other embodiments, a combination of first dielectric passivation film 241, second dielectric passivation film 242, and metal layer 243 has a thickness range of about 15 to about 50 Å. In some embodiments, a combination of the first dielectric passivation film 241, the second dielectric passivation film 242, and the metal layer 243 has a thickness of about 30 Å. In other embodiments, a total thickness of the first dielectric passivation film 241 and the second dielectric passivation film 242 is greater than a thickness of the metal layer 243.

In other embodiments, as shown in FIG. 3B, one dielectric passivation film 241 is applied over the CNT 230′ and the metal layer 243 is applied over the dielectric passivation film 241. In some embodiments, when only one dielectric passivation film is used, a thickness of the one dielectric passivation film 241 is larger than a thickness of the metal layer 243.

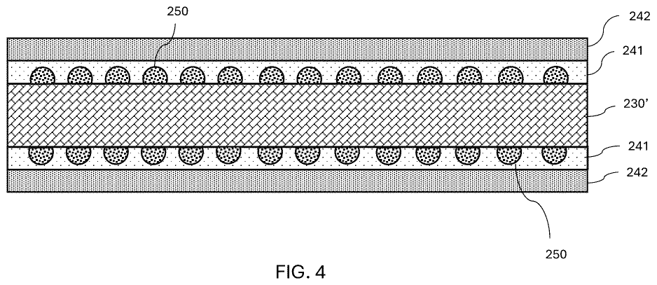

In other embodiments, as shown in FIG. 4, a metal seed layer 250 is deposited on the an outer surface of the CNT 230′. In certain embodiments, the metal seed layer 250 provides resistance to degradation by hydrogen ions and radicals during EUV or DUV exposure. As shown in FIG. 4, the metal seed layer 250 is deposited as an island-shape or ball-shape structure on a surface of the CNT 230′.

In some embodiments, the metal seed layer 250 includes a metal selected from ruthenium (Ru) or titanium (Ti). In other embodiments, the metal seed layer 250 includes a metal oxide selected from a ruthenium oxide or a titanium oxide. In other embodiments, the metal seed layer 250 includes a metal nitride including RuN or TiN. In some embodiments, the presence of the metal seed layer 250 provides improved protection for the CNT pellicle membrane 230 from hydrogen radicals and ions during EUV or DUV exposure. In some embodiments, the metal seed layer 250 increases the adhesion area for the dielectric passivation film 241 as it is deposited over the metal seed layer 250. In some embodiments, the metal seed layer 250 is deposited on an outer surface of the CNT 230′ by PVD, CVD, plasma-enhanced CVD, ALD, plasma-enhanced ALD, e-beam evaporation, electroless deposition, electrodeposition, sputtering, or IBD. In certain embodiments, the average particle size of the island-shape or ball-shape structures of the metal seed layer 250 ranges from about 0.5 to 6 nanometers (nm).

In the embodiment of FIG. 4, the first dielectric passivation film 241 and the second dielectric passivation film 242 include oxides, nitrides, and oxynitrides of silicon, titanium, and aluminum. In some examples, the materials for the first dielectric passivation film 241 and the second dielectric passivation film 242 are selected from SiO, SiO₂, SiN, Si₃N_{4,} SiOxNy, TiO₂, TiN, TiOₓN_{y}, TiSiO, TiSiN, Al₂O₃, AlON, AlN and/or the combination thereof. In some embodiments, the presence of the first and second dielectric passivation films 241, 242 improve the transmittance of the CNT pellicle membrane 230. In some embodiments, the first dielectric passivation film 241 includes a silicon oxide and the second dielectric passivation film 242 includes a silicon nitride. In other embodiments, the first dielectric passivation film 241 includes silicon nitride and the second dielectric passivation film 242 includes silicon oxide. In some embodiments, the first dielectric passivation film 241 and the second dielectric passivation film 242 are disposed by PVD, CVD, plasma-enhanced CVD, ALD, plasma-enhanced ALD, e-beam evaporation, electroless deposition, electrodeposition, or IBD. In some examples, the first dielectric passivation film 241 has a thickness range of about 5 to about 20 Angstroms (Å). In some examples, the second dielectric passivation film 242 has a thickness range of about 5 to about 20 Å.

In some embodiments, the metal seed layer 250 is deposited as a pure metal. In some embodiments, the pure metal is Ru or Ti. In some embodiments, the first dielectric passivation film 241 is an oxide or nitride, and when the first dielectric passivation film 241 is deposited over the metal seed layer 250 of pure metal, an oxide or nitride of the pure metal (e.g.—RuO, RuN, TiO₂, or TiN) is formed over a surface of the metal seed layer 250.

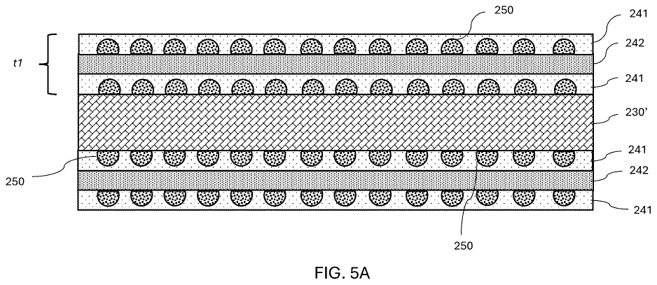

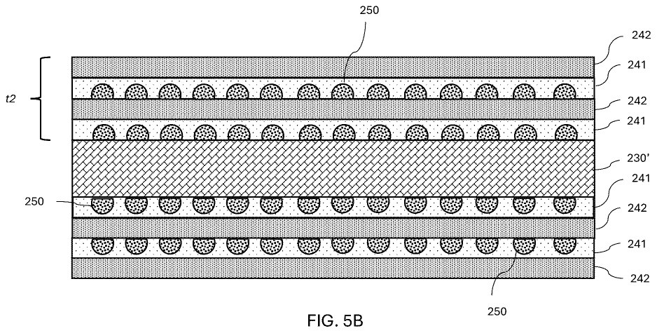

In some embodiments, as shown in FIGS. 5A and 5B, the metal seed layer 250, the first dielectric passivation film 241, and the second dielectric passivation film 242 are repeated in multiple layers. In some embodiments, the surface of the CNT 230′ includes a multi-layer structure comprising a plurality of metal seed layers 250, first dielectric passivation films 241, and second dielectric passivation films 242 repeated over the surface of the CNT 230′. In some embodiments, the presence of the multiple metal seed layers 250 provides improved protection of the CNT pellicle membrane 230 from hydrogen radicals and ions during EUV or DUV photolithography. In some embodiments, the multiple metal seed layers 250 provide increased adhesion areas for the first dielectric passivation films 241 during deposition of the first dielectric passivation films 241. In the example of FIG. 5A, a thickness t1 of the multi-layer structure is range of about 10 to 40 Å. In the example of FIG. 5B, a thickness t2 of the multi-layer structure ranges from about 15 to 50 Å. The number of layers is not limited to those shown in FIGS. 5A and 5B. In some embodiments, additional layers of the multi-layer structure are included with an overall thickness of about 50 Å or less. The materials for the metal seed layers 250, first dielectric passivation films 241, and second dielectric passivation films 242, in FIGS. 5A and 5B, are similar to those described above for the embodiments of FIGS. 3B and 4.

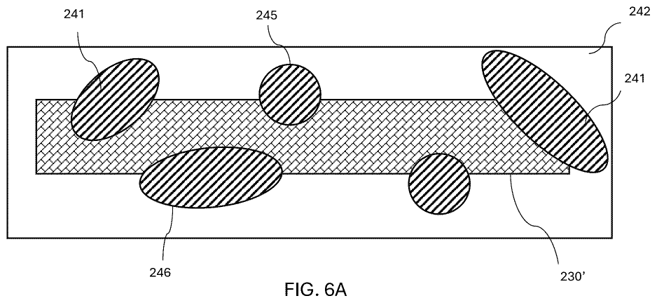

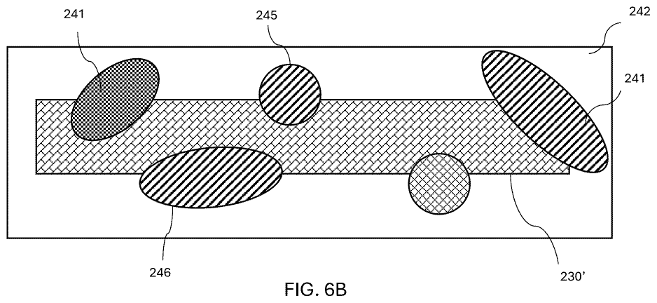

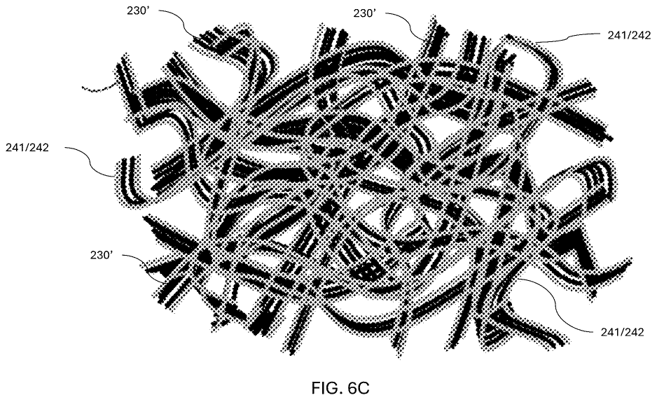

In some embodiments, the first dielectric passivation films 241 and the second dielectric passivation films 242 are made of crystals. In some embodiments, the crystal films 241, 242 are deposited as nanograins or as a continuous film over the surface of the CNT 230′. In some embodiments, the nanograins of the first dielectric passivation film 241 have the same grain orientation (FIG. 6A). In other embodiments, the nanograins of the first dielectric passivation film 241 have different grain orientations, as shown in FIG. 6B. In some embodiments, the mechanical and optical properties of the silicon oxide and silicon nitride nanograins of the dielectric passivation films are influenced by factors including grain size, microstructure, and crystal orientation.

In some embodiments, the nanograins of the dielectric passivation film 241 have a plurality of spherical 245 and ellipsoid 246 shapes (FIGS. 6A and 6B). In certain embodiments, the ellipsoid-shaped nanograins 244 have a length of about 0.5 nm to about 10 nm. In some embodiments, the average diameter of the spherical-shaped nanograins ranges from about 0.5 nm to about 10 nm.

In the embodiments of FIGS. 6A and 6B, the first dielectric passivation film 241 is deposited as nanograins on a surface of the CNT 230′. In some embodiments, the second dielectric passivation film 242 is deposited as a continuous film over the first dielectric passivation film 241 (also a continuous film) and a bundle or networks of CNTs 230′, as shown in FIG. 6C. In other embodiments, both the first dielectric passivation film 241 and the second dielectric passivation film 242 are deposited as nanograins.

In some embodiments, surfaces of the CNTs 230′ are subjected to a pre-treatment to generate more bonding site surfaces prior to depositing the dielectric passivation film 241 or metal seed layer 250 on surfaces of the CNTs 230′. In some embodiments, the CNTs 230′ are thin sheets of graphene (e.g., graphite monolayer) that are tubular with open or closed ends (FIG. 2C). In some embodiments, the arrangement of wall carbon atoms in the cylindrical structure of the CNT is the arrangement of the same regular carbon hexagon rings found in graphite. In some embodiments, the pre-treatment is a plasma surface treatment process selected from capacitively-coupled plasma (CCP) or inductively-coupled plasma (ICP). In some embodiments, the CCP or ICP provides a surface functionalization of CNTs 230′. In some embodiments, the plasma surface treatment generates active sites on the surface of the CNTs 230′. In some embodiments, the plasma surface treatment creates an oxidative or reductive environment to introduce different types of functional groups onto the CNT surface, affecting the functional properties of the CNTs 230′. In certain embodiments, the type of functionalization can be tuned by the plasma conditions (i.e., feeding gas, power, and duration of treatment), resulting in oxygen-containing (hydroxyl, carbonyl, carboxyl, etc.), nitrogen-containing (amine, amide, nitrile, etc.), or fluorine-containing groups. In some embodiments, a feeding gas includes one or more selected from H₂, O₂, N₂, N₂O, NH₃, H₂O, O₃, He, and/or Ar. In certain embodiments, the processing temperature for the plasma surface treatment ranges from about 100 to about 500 °C with a duration of treatment from about 1 to about 50 seconds.

In other embodiments, a thermal soaking with a solvent is performed on the CNTs 230′ prior to depositing the dielectric passivation film 241 or metal seed layer 250 on surfaces of the CNTs 230′. In some embodiments, the thermal soaking increases a contact area and reduces the contact resistance of the CNTs 230′. In some embodiments, a solvent including one or more of H₂O , O₂, and/or O₃ is used to soak the CNTs 230′. In certain embodiments, the processing temperature for the thermal soak treatment ranges from about 100 to about 500 °C with a duration of treatment from about 1 to about 50 seconds.

In some embodiments, a post-treatment is applied to the dielectric passivation films 241, 242 and the metal layer 243. In some embodiments, the post-treatment is performed on the dielectric passivation films 241, 242 and the metal layer 243 to remove impurities including hydrogen ions, and also remove dangling bonds to create more Si—O or Si—N bonds. In other embodiments, the post-treatment is performed on the dielectric passivation films 241, 242 and the metal layer 243 to provide oxygen doping or nitrogen doping. In some embodiments, the dopant concentration in the network of CNTs 230′ is about 5 at. % to about 15 at. %. Dopant concentrations above 15 at. % can decrease transmission of the pellicle membrane and reduce the mechanical strength of the CNT pellicle membrane 230.

In some embodiments, the CCP or ICP of the post-treatment provides a surface functionalization of dielectric passivation films 241, 242, and the metal layer 243. In some embodiments, the plasma surface treatment generates active sites on the surface of the dielectric passivation films 241, 242, and the metal layer 243. In some embodiments, the plasma surface treatment creates an oxidative or reductive environment to introduce different types of functional groups onto the dielectric passivation films 241, 242 and the metal layer 243, affecting the functional properties of the dielectric passivation films 241, 242 and the metal layer 243. In certain embodiments, the type of functionalization can be tuned by the plasma conditions (i.e., feeding gas, power, and duration of treatment), resulting in oxygen-containing (hydroxyl, carbonyl, carboxyl, etc.), nitrogen-containing (amine, amide, nitrile, etc.), or fluorine-containing groups. In some embodiments, a feeding gas includes one or more selected from H₂, O₂, N₂, N₂O, NH₃, H₂O, O₃, He, and/or Ar. In certain embodiments, the processing temperature for the plasma surface treatment ranges from about 100 to about 300 °C with a duration of treatment from about 1 to about 50 seconds.

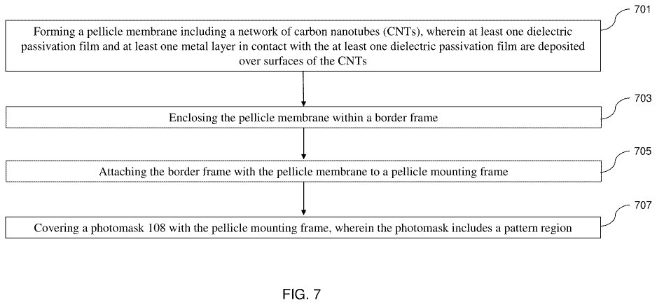

FIG. 7 is a flowchart for a method of forming a photomask-pellicle assembly 205. The method includes step 701 of forming a pellicle membrane 230 including a network of CNTs 230′. In some embodiments, at least one dielectric passivation film 241, 242 and at least one metal layer 243 or 250 in contact with the at least one dielectric passivation film 241, 242 are deposited over surfaces of the CNTs. The method includes step 703 of enclosing the pellicle membrane 230 within a border frame 232. The method includes step 705 of attaching the border frame 232 with the pellicle membrane 230 to a pellicle mounting frame 222. The method includes step 707 of covering a photomask 108 with the pellicle mounting frame. In some embodiments, the photomask includes a pattern region 210.

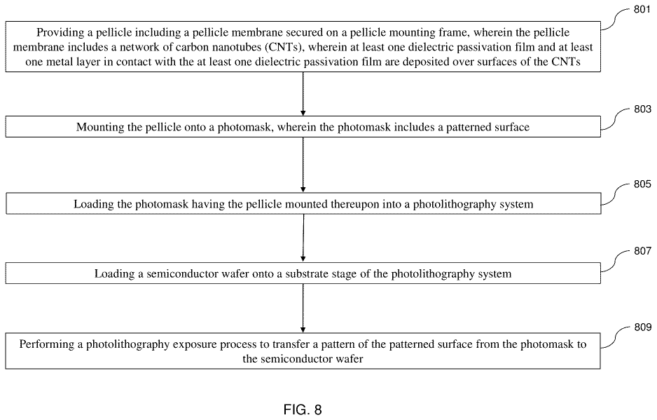

FIG. 8 is a flowchart for a method of manufacturing a semiconductor device. The method includes step 801 of providing a pellicle 114 including a pellicle membrane 230 secured on a pellicle mounting frame 222. In certain embodiments, the pellicle membrane includes a network of CNTs 230′. In certain embodiments, at least one dielectric passivation film 241, 242 and at least one metal layer 243 or 250 in contact with the at least one dielectric passivation film are deposited over surfaces of the CNTs. The method includes step 803 of mounting the pellicle 114 onto a photomask 108, wherein the photomask includes a patterned surface 210. The method includes step 805 of loading the photomask having the pellicle mounted thereupon into a photolithography system 100. The method includes step 807 of loading a semiconductor wafer 116 onto a substrate stage 112 of the photolithography system. The method includes step 809 of performing a photolithography exposure process to transfer a pattern 210 of the patterned surface from the photomask 108 to the semiconductor wafer 116.

Thus, examples of the present disclosure provide a multi-layered CNT pellicle with high durability and high transmission that is resistant to damage caused by hydrogen radicals and ions. The multi-layered CNT pellicle of the present disclosure are especially suitable for use in ultraviolet lithography systems, such as EUV lithography systems.

In one example, the present disclosure provides a method of forming a photomask-pellicle assembly. The method includes forming a pellicle membrane including a network of carbon nanotubes (CNTs). In some embodiments, at least one dielectric passivation film and at least one metal layer in contact with the at least one dielectric passivation film are deposited over surfaces of the CNTs. The method includes enclosing the pellicle membrane within a border frame. The method includes attaching the border frame with the pellicle membrane to a pellicle mounting frame. The method includes covering a photomask with the pellicle mounting frame, wherein the photomask includes a pattern region.

In certain embodiments, the at least one dielectric passivation film includes a first dielectric passivation film deposited over outer surfaces of the CNTs and a second dielectric passivation film deposited over the first dielectric passivation film. In some embodiments, the first dielectric passivation film and the second dielectric passivation film include a material selected from the group consisting of silicon oxide, silicon nitride, SiOₓN_{y}, TiO₂, TiN, TiOₓN_{y}, TiSiO, TiSiN, Al₂O₃, AlON, and AlN. In some embodiments, the first dielectric passivation film includes silicon oxide. In some embodiments, the second dielectric passivation film includes silicon nitride. In some embodiments, the at least one metal layer includes a metal layer deposited on a surface of the first dielectric passivation film. In some embodiments, the at least one metal layer includes a metal layer deposited on a surface of the second dielectric passivation film. In some embodiments, a thickness range of the first dielectric passivation film and the second dielectric passivation film is 5 to 20 angstroms. In other embodiments, the at least one metal layer includes a metal selected from the group consisting of Ru, Ti, ruthenium oxide, and titanium oxide. In some embodiments, the at least one metal layer includes a metal seed layer deposited on outer surfaces of the CNTs.

In another example, a method of manufacturing a semiconductor device is provided. The method includes providing a pellicle including a pellicle membrane secured on a pellicle mounting frame. In some embodiments, the pellicle membrane includes a network of CNTs. In some embodiments, at least one dielectric passivation film and at least one metal layer in contact with the at least one dielectric passivation film are deposited over surfaces of the CNTs. The method includes mounting the pellicle onto a photomask, wherein the photomask includes a patterned surface. The method includes loading the photomask having the pellicle mounted thereupon into a photolithography system. The method includes loading a semiconductor wafer onto a substrate stage of the photolithography system. The method includes performing a photolithography exposure process to transfer a pattern of the patterned surface from the photomask to the semiconductor wafer.

In certain embodiments, the photolithography exposure process generates light selected from deep ultraviolet (DUV) light or extreme ultraviolet (EUV) light. In some embodiments, the at least one dielectric passivation film includes a first dielectric passivation film including silicon nitride and a second dielectric passivation film includes silicon oxide. In other embodiments, the at least one metal layer includes a metal seed layer deposited on outer surfaces of the CNTs. In some embodiments, the metal seed layer includes a plurality of island-shaped or ball-shaped structures. In some embodiments, a plurality of dielectric passivation films and a plurality of metal layers are deposited over the surfaces of the CNTs.

In another example, a pellicle for semiconductor photolithography is provided. The pellicle includes a pellicle membrane including a bundle of CNTs. In some embodiments, at least one dielectric passivation film and at least one metal layer in contact with the at least one dielectric passivation film are deposited over surfaces of the CNTs. A border frame is attached to the pellicle membrane along a peripheral region of the pellicle membrane. A mounting frame is attached to the border frame.

In some embodiments, the at least one dielectric passivation film includes a material selected from the group consisting of silicon oxide, silicon nitride, SiOₓN_{y}, TiO₂, TiN, TiOₓN_{y}, TiSiO, TiSiN, Al₂O₃, AlON, and AlN. In some embodiments, the at least one dielectric passivation film includes a first dielectric passivation film deposited as nanograins. In some embodiments, the at least one dielectric passivation film includes a second dielectric passivation film deposited as a continuous film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of forming photomask-pellicle assembly, comprising:
forming a pellicle membrane including a network of carbon nanotubes (CNTs), wherein at least one dielectric passivation film and at least one metal layer in contact with the at least one dielectric passivation film are deposited over surfaces of the CNTs;
enclosing the pellicle membrane within a border frame;
attaching the border frame with the pellicle membrane to a pellicle mounting frame; and
covering a photomask with the pellicle mounting frame, wherein the photomask includes a pattern region.

2. The method of claim 1, wherein the at least one dielectric passivation film includes a first dielectric passivation film deposited over outer surfaces of the CNTs and a second dielectric passivation film deposited over the first dielectric passivation film.

3. The method of claim 2, wherein the first dielectric passivation film and the second dielectric passivation film comprise a material selected from the group consisting of silicon oxide, silicon nitride, SiOₓN_{y}, TiO₂, TiN, TiOₓN_{y}, TiSiO, TiSiN, Al₂O₃, AlON, and AlN.

4. The method of claim 3, wherein the first dielectric passivation film comprises silicon oxide.

5. The method of claim 4, wherein the second dielectric passivation film comprises silicon nitride.

6. The method of claim 4, wherein the at least one metal layer comprises a metal layer deposited on a surface of the first dielectric passivation film.

7. The method of claim 5, wherein the at least one metal layer comprises a metal layer deposited on a surface of the second dielectric passivation film.

8. The method of claim 5, wherein a thickness range of the first dielectric passivation film and the second dielectric passivation film is 5 to 20 angstroms.

9. The method of claim 1, wherein the at least one metal layer comprises a metal selected from the group consisting of Ru, Ti, ruthenium oxide, and titanium oxide.

10. The method of claim 1, wherein the at least one metal layer comprises a metal seed layer deposited on outer surfaces of the CNTs.

11. A method of manufacturing a semiconductor device, comprising:
providing a pellicle including a pellicle membrane secured on a pellicle mounting frame, wherein the pellicle membrane includes a network of carbon nanotubes (CNTs), wherein at least one dielectric passivation film and at least one metal layer in contact with the at least one dielectric passivation film are deposited over surfaces of the CNTs;
mounting the pellicle onto a photomask, wherein the photomask includes a patterned surface;
loading the photomask having the pellicle mounted thereupon into a photolithography system;
loading a semiconductor wafer onto a substrate stage of the photolithography system; and
performing a photolithography exposure process to transfer a pattern of the patterned surface from the photomask to the semiconductor wafer.

12. The method of claim 11, wherein the photolithography exposure process generates light selected from deep ultraviolet (DUV) light or extreme ultraviolet (EUV) light.

13. The method of claim 11, wherein the at least one dielectric passivation film includes a first dielectric passivation film comprising silicon nitride and a second dielectric passivation film comprises silicon oxide.

14. The method of claim 11, wherein the at least one metal layer comprises a metal seed layer deposited on outer surfaces of the CNTs.

15. The method of claim 14, wherein the metal seed layer comprises a plurality of island-shaped or ball-shaped structures.

16. The method of claim 11, wherein a plurality of dielectric passivation films and a plurality of metal layers are deposited over the surfaces of the CNTs.

17. A pellicle for semiconductor photolithography, comprising:
a pellicle membrane including a bundle of carbon nanotubes (CNTs), wherein at least one dielectric passivation film and at least one metal layer in contact with the at least one dielectric passivation film are deposited over surfaces of the CNTs;
a border frame attached to the pellicle membrane along a peripheral region of the pellicle membrane; and
a mounting frame attached to the border frame.

18. The pellicle of claim 17, wherein the at least one dielectric passivation film comprises a material selected from the group consisting of silicon oxide, silicon nitride, SiOₓN_{y}, TiO₂, TiN, TiOₓN_{y}, TiSiO, TiSiN, Al₂O₃, AlON, and AlN.

19. The pellicle of claim 18, wherein the at least one dielectric passivation film comprises a first dielectric passivation film deposited as nanograins.

20. The pellicle of claim 19, wherein the at least one dielectric passivation film comprises a second dielectric passivation film deposited as a continuous film.
